(19) United States
(12) Patent Application Publication
(10) Pub. No.: US 2010/0252717 A1
(43) Pub. Date: Oct. 7, 2010

(54) ACTIVE-PIXEL SENSOR

(76) Inventors: Benoit DUPONT, Brussels (BE); Bart DIERICKX, Edegem (BE)

Correspondence Address: BACON & THOMAS, PLLC, 625 SLATERS LANE, FOURTH FLOOR, ALEXANDRIA, VA, 22314-1176, US

(21) Appl. No.: 12/567,079

(22) Filed: Sep. 25, 2009

Related U.S. Application Data
(63) Continuation-in-part of application No. 12/239,855, filed on Sep. 29, 2008, now abandoned.

(51) Int. Cl. H01L 31/102; H01L 27/146; H03F 3/08

(52) U.S. Cl. 250/208.1; 250/214 A

(57) ABSTRACT

The invention relates to an active-pixel sensor including an electromagnetic radiation detector, comprising a transistor amplifier, a series memory capacitor and a parallel load capacitor that are driven by the transistor amplifier.

This is a continuation-in-part application of application Ser. No. 12/239,855, filed Sep. 29, 2008.

The invention relates to an active-pixel sensor including an electromagnetic radiation detector, comprising a transistor amplifier having, wherein the input of the transistor amplifier is coupled to the electromagnetic radiation detector for generating an electrical signal output having a magnitude that is a function of the charge input generated by the electromagnetic radiation detector.

### TECHNICAL BACKGROUND

Active pixels are very diverse in nature and performance. They have features that are adapted to their specific application and the performance parameters. Such features and parameters are e.g.
Having low noise, which is obtained in various ways. One state of the art, generic, method is called “correlated double sampling” (CDS).
Having a “synchronous shutter” (SS) (also called “snapshot operation”), meaning that all pixels in the array are sensitive at the same time. A special type of “synchronous shutter” is the “pipelined synchronous shutter” (PSS), which has the additional feature that the data of the previous frame are read out while the next frame is being acquired (integrated). The other type of synchronous shutter is “triggered synchronous shutter” (TSS), where integration times and readout time do not overlap.

However, the most common pixel structure such as the 3T pixel structure does not feature CDS nor SS. The common pinned diode 4T pixel, although it has excellent noise performance due to CDS, cannot have PSS.

It takes at least 5 transistors and a pinned photodiode to realize a pixel that has CDS and PSS. And even in that case, the performance of the pixel is far from optimal.

Active-pixel sensors almost always have a provision called “reset”. Prior to the state of charge integration, the active-pixel storage node, which is often the radiation detector itself, or the so-called “floating diffusion”, has to be reset to a known initial voltage. Plenty of examples of this kind of operation and implementations are known from the prior art.

Depending on the method of operation, the reset and hence the active-pixel operation may have different levels of performance. For example, when using “raw” operation, the active-pixel is reset and the active pixel's signal is sampled after a certain integration time being considered as the final signal without further processing. This mode of operation is the simplest possible, but the signal is subject to a significant fixed pattern noise (FPN), thermal noise (kTC-noise) and environmental noise such as substrate noise, power supply noise and electromagnetic interference (EMI).

These drawbacks are at least partially avoided by a hard reset with double sampling or a soft reset with double sampling. In the hard reset mode with double sampling, in order to obtain one signal reading, two samples are taken and subtracted from each other. One sample is the pixel's reading at the end of the integration time, i.e. just before the reset, and the second signal is the pixel's reading just after the reset. Hard reset means that the reset provision, which is usually implemented as a MOSFET, acts merely as a real switch: while closed, its resistance is sufficiently low so that the node to be reset comes quickly to the external reset voltage at the drain of the reset MOSFET.

As the fixed pattern noise (FPN) is mainly due to an offset in the pixel's MOSFETs, the difference between the two readings is mostly free of the FPN. As a result, the fixed pattern noise is avoided, while the thermal (kTC) noise, however, is not suppressed.

While the gate-source voltage of the reset MOSFET is larger than the threshold voltage for the hard reset with double sampling, the gate-source voltage does not exceed the threshold voltage for the soft reset with double sampling. Therefore, in “Soft Reset” operation, the reset MOSFET will not act as a sufficiently perfect switch. As with hard reset, a large part of the fixed pattern noise is cancelled by the soft reset. Further, a soft reset also allows for a significant suppression of the thermal kTC noise. However, the soft reset has a distinct drawback, as it results in image lag, which is a parasitic memory effect between consecutive images due to the fact that the reset operation is incomplete.

By using the so-called active reset, the fixed pattern noise is suppressed by feedback applied to the reset voltage during the time that the reset MOSFET is on. Thermal noise is reduced as well, and active reset does not suffer from image lag. However, this mode of operation has drawbacks in versatility, signal range, power and unwanted artifacts.

Generally, correlated double sampling is considered as the best reset technique, as both the fixed pattern noise and the thermal noise are completely cancelled. However, not all types of active pixels are suitable to be operated with correlated double sampling. Active pixels, for which the photodiode is at the same time the floating diffusion, such as classic active-pixels with three transistors (3T), cannot be operated with (in-pixel or on-chip) correlated double sampling. More generally, today there is no active-pixel architecture where the photodiode node is equal to the floating diffusion and which has a mode of operation that achieves very good noise suppression, has no image lag or other hidden flaws or complexity.

In addition, many existing pixel topologies do not allow the so-called electronic “synchronous shutter” or “snapshot” operation, in which all photodiodes are reset simultaneously and their respective voltages after integration are sensed simultaneously, ensuring time consistency in the image formed by multiples of such pixels.

In the prior art, many examples of Snapshot capable pixel structures exist. However, such pixel structures are usually unable to perform both CDS operation and Snapshot. A solution capable of performing both operation has been developed in the art based on Pinned (or buried) photodiodes. However it requires non-standard implantation techniques and in many cases, these technologies can not be selected for the target application. For instance, hybrid detectors are not yet compatible with pinned diode pixel structures.

### SUMMARY OF THE INVENTION

The present invention provides a versatile active pixel architecture capable of performing pipelined synchronous shutter operation, snapshot operation, rolling shutter operation, CDS, high dynamic output without requiring non-standard CMOS technology.

Another feature of the invention is a circuit and method to reset the floating diffusion of such pixel by multiple reset pulses on multiple reset transistors, so that the effect of external noise sources is strongly reduced.

Advantageously, in an embodiment of the present invention, a multiple stage active pixel sensor is provided. A first stage comprises one or more reset transistors, a photodiode and a first amplifier. A second stage comprises or consist of a series storage capacitor, i.e. a storage capacitor located at a position between an output of the amplifier or output of the first stage and an output stage, a first variable resistor or switch connecting the output of the first stage and a first electrode of the capacitor and two (second and third) variable resistors or switch each connecting respectively the first and a second electrode of the capacitor to respective first and second voltage signals. Finally the last or output stage comprises an amplifier, a fourth variable resistor or switch, connecting the output of the pixel to a column readout. An advantage of this architecture is that it is as versatile as a so-called 4T pixel without requiring non-standard CMOS process.

A capacitor called “C_{P}” is used for some modes of operation to complement the storage capacitor “C_{MEM}”. C_{P} has a value of the same order of magnitude as C_{MEM}. C_{P} can have a size relative to the memory capacitor C_{MEM} such that C_{P}>20% of C_{MEM}.

An array of such pixel structures is provided, e.g. in rows and columns. In a first mode of operation, the invented pixel structure is able to perform pipelined shutter operation. To do so, all photodiodes of the array are reset simultaneously using the first variable resistor(s) or switch(es). Two such switches may be connected in series which may act also as a single switch or may be replaced by a single switch.

Then, after an exposure time, the second and third variable resistors are set to low impedance, whereby the first voltage signal is a reference voltage which could e.g. be ground potential, and the second voltage signal being a reference voltage at a higher or high voltage. Then simultaneously, the second variable resistors of all pixels are set to high impedance, and the first variable resistor is set to low impedance. This samples the output voltage of first stage onto the storage capacitor of the second stage. Then simultaneously, the first variable resistor is set to high impedance, latching the pixel data. The third variable resistor is set to high impedance, and second variable resistor is set back to low impedance. The pixel data is then available for voltage readout using classically the last stage of the pixel. In addition to this operation, it is clear that the photodiode can be reset again once the first variable resistor is set to high impedance. The readout is independent of the integration and can be performed during the following frame integration time. Such mode of operation is called pipelined snapshot of pipelined synchronous shutter.

In a second mode of operation, the previously described reset and readout scheme can be applied on a row by row basis and not simultaneously on all pixels of the array. The pixel architecture does not limit the user to snapshot operation. Therefore, classic “rolling shutter” operation is possible.

In a third mode of operation, the pixel is capable of increasing the output voltage range of the pixel. In a first mode of operation, the column voltage of the output stage is at best equal to the photodiode voltage minus two times the transistor threshold voltage due to the structure of first and last (output) stage amplifiers. Therefore, it is impossible to readout diode values lower than two time the transistor threshold value. The pixel architecture overcomes this limitation using the following operation. All photodiodes of the array are reset simultaneously using the first variable resistor.

Then, after an exposure time, second and third variable resistors are set to low impedance, the first voltage signal being a reference voltage at ground potential, and the second voltage signal being a reference voltage at a high or higher voltage. Then simultaneously, the second variable resistors of all pixels are set to high impedance, and the first variable resistor is set to low impedance. This samples the output voltage of first stage onto the storage capacitor of second stage. Then simultaneously, first variable resistor is set to high impedance, latching the pixel data. The third variable resistor is set to high impedance. The first voltage signal which is a reference voltage is then brought to higher voltage than ground potential, 1.5V for instance, and the second variable resistor is set back to low impedance. Doing so results in a voltage translation of the sampled voltage towards high voltage. The translation being the difference between second voltage signal which has a high value and ground. This compensates for the loss of one threshold voltage in the first stage of the pixel. As a result, the output voltage range of the pixel is increased. The pixel data is then available for voltage readout using classically the last stage of the pixel. In addition to this snapshot operation, it is clear that the photodiode can be reset again once the first variable resistor is set to high impedance. This mode of operation is thus also compatible with pipelined snapshot.

In a fourth mode of operation, the previously described reset and readout scheme can be applied on a row by row basis and not simultaneously on all pixels of the array. The invented pixel architecture does not limit the user to snapshot operation. Therefore, rolling shutter high output range is possible.

In a fifth mode of operation (which can be combined with several of the other modes listed above), the invented pixel is capable of performing correlated double sampling (CDS). On a row by row basis, the photodiode is reset using the variable resistor or switch 3.

The second and third variable resistors are set to low impedance, The first voltage signal is a reference voltage at ground potential, whereas the second voltage signal is a reference voltage at a high or higher voltage. The first variable resistor is set to low impedance. This samples the output voltage of first stage onto the storage capacitor of second stage. Then first variable resistor is set to high impedance, latching the reset voltage of the photodiode. After integration time, the third variable resistor is set to high impedance. The second variable resistor is set back to low impedance. The first variable resistor is set to low impedance and the last stage fourth variable resistance connecting the pixel second amplifier to the column select line is set to low impedance. Across the storage capacitor, the actual reset voltage is subtracted from the signal voltage, performing a correlated double sampling without requiring additional CMOS process steps during manufacturing process.

In a sixth mode op operation, CDS operation is done in triggered synchronous shutter operation. It is similar to the fifth mode of operation, yet, all switching of the variable resistors is done for all pixels in parallel, instead of row-by-row. Only at the moment of readout, the pixels data are read out row-by-row.

In order to have a good performance in this mode of operation, one needs a capacitor called “C_{P}” to complement the memory element “C_{MEM}”. This C_{P} is necessary as, when the CDS is executed by opening the switches (variable resistances) in series with C_{MEM}, the capacitive load seen by the source followers driving C_{MEM}, becomes very low. As the source followers have a small load capacitance (“C_{load}”), their output voltage noise (proportional to \sqrt{k·T/C_{load}}) becomes too high and jeopardizes the noise suppressing properties of the CDS. Also, C_{P} is necessary to stabilize the voltage on the output source follower during subsequent readout, as in FIG. 9c. C_{P} must have a value of the same order of magnitude as C_{MEM} to have a sufficient stabilizing effect.

Additionally, it is the object of the invention to provide an active-pixel sensor including an electromagnetic radiation detector, comprising a transistor amplifier having an input and an output, wherein the input of the transistor amplifier is coupled to the electromagnetic radiation detector for generating an electrical signal output having a magnitude that is a function of the charge input generated by the electromagnetic radiation detector. An advantage of the present invention is the possibility for resetting an active-pixel sensor with an electromagnetic radiation detector that is equal to the floating diffusion, which allows for an image lag free operation and sufficient suppression of temporal noise sources, such as power supply noise.

The present invention also provides an active pixel having at least two variable resistances coupled in series, wherein the at least two variable resistances are adapted for being turned on and off for resetting the charge input to the transistor amplifier to a predetermined signal level, and wherein the first variable resistor is coupled to the electromagnetic radiation detector.

Accordingly, it is an essential idea of the invention to turn on and off at least two variable resistances, coupled in series for resetting the photodiode or floating diffusion. This is advantageous over the prior art, as the present invention allows to soften the effect of certain noise sources that are inherent to the devices in the pixels circuit or that enter the pixel signal via supply lines, substrate or other connections. The present invention allows further for an image lag free and simple operation, wherein the supply voltage temporal noise is tempered or suppressed.

According to a preferred embodiment of the invention, the at least two variable resistances are adapted for being alternately, concurrently or first concurrently and then alternately turned on and off. Turning on concurrently the at least two variable resistances allow for obtaining a good initial signal level for preventing image lag. This is then followed by turning on and off the at least two variable resistances alternately for reducing or silencing the noise in the signal further.

In general, the last variable resistance can be coupled to any voltage source. However, according to a preferred embodiment of the invention, the last variable resistance is coupled to a DC voltage source. In other words, the voltage to which the floating diffusion is reset to can be provided as a DC voltage, in particular a voltage that is DC during the time that the active pixels are being reset.

According to another preferred embodiment of the invention, the last variable resistance is coupled to an output of a feedback circuit, which is adapted for sensing the charge input. This means that a voltage that is provided to the last variable resistance is the output voltage of a feedback circuit, such as an amplifier, which is sensing the charge input generated by the electromagnetic radiation detector.

According to a preferred embodiment of the invention, the electromagnetic radiation detector is provided as a monolithic or hybrid photodiode or as a monolithic or hybrid photoresistor. In this manner the present invention is advantageous, since it allows a solution for hybrid active-pixels, wherein the photoreceptors, such as photodiodes or photoresistors, are connected to the floating diffusion via a bump or wire bond for allowing a image lag free operation and suppression of temporal noise.

According to another preferred embodiment of the invention, a plurality of at least two variable resistances coupled in series are provided in parallel. Alternatively, the single variable resistance can be provided in parallel to a single or a plurality of at least two variable resistances. It is further preferred to increase the number of variable resistances coupled in series to obtain a lower thermal noise on the floating diffusion.

According to still another preferred embodiment of the invention, the variable resistance includes a transistor having a first main electrode (drain or source), a second main electrode (source or drain), and a gate, and wherein the gate is adapted for being supplied with a reset signal. A main electrode of a transistor is a power electrode or an electrode in the current path of the transistor that determines its output such as a drain or source electrode in contrast to a control electrode such as a gate which is normally a control input to the transistor. Only the drain of the “last” transistor is tied to the supply voltage. The reset signal can be, for example a pulse train. The reset signal can turn on and off the variable resistor, i.e. change its resistance value.

It is further preferred that the switch transistor is provided as a MOSFET. The active-pixel may comprise further transistors, such as MOSFETs, JFETs and BJTs, for reading signals and multiplexing signal outputs from an array of pixels.

The present invention also provides a method for resetting an active-pixel sensor, comprising the step of alternately turning on and off at least two variable resistances coupled in series for resetting a charge input to a predetermined signal level. Accordingly, it is an essential idea of the invention to alternately turn on and off the at least two variable resistances coupled in series for resetting the charge input, which may be generated by an electromagnetic radiation detector, to a predetermined signal level. The variable resistances can be provided as MOSFETs, wherein a reset signal is supplied to the gate. The method according to the invention is advantageous over prior art, since it allows to combine active-pixels with electromagnetic radiation detectors such as photodiodes equal to the floating diffusion, and hence not requiring pinned photodiodes and the associated expensive technologies around. The invention further allows for an image lag free operation of active pixels while suppressing the temporal noise far below the thermal noise level.

According to another preferred embodiment of the invention, the method further comprises the step of consecutively turning on the at least two variable resistances prior to alternately turning on and off the at least two variable resistances. This means that the at least two variable resistances are first turned on and then alternately turned on and off for resetting the charge input to a predetermined signal level.

According to another preferred embodiment of the invention, the charge input is provided by an electromagnetic radiation detector for generating an electrical signal output having a magnitude that is a function of a charge input. It is preferred that the electromagnetic radiation detector is provided as a photodiode or a photoresistor, wherein the photodiode or the photoresistor can be provided monolithic or hybrid. In this way, the method according to the invention is applicable for monolithic or hybrid active-pixels, wherein the photoreceptors, such as photodiodes or photoresistors, are connected to the floating diffusion via a bump or wire bond or other means.

According to another preferred embodiment of the invention, the method further comprises the step of loading the at least two variable resistances with a DC voltage. This means that a reset voltage to which the floating diffusion is reset, can be provided as a DC voltage. In other words, the at least two variable resistances can be coupled at one end to a DC voltage and at the other end to the electromagnetic radiation detector.

According to another preferred embodiment of the invention, the method further comprises the step of loading the at least two variable resistances with a voltage which is an output of a feedback circuit sensing the charge input. The feedback circuit can be provided as an amplifier, such as a charge amplifier that is sensing the charge of the floating diffusion.

The present invention also provides a method of use for an active-pixel sensor according to the invention and/or for a method according to the invention for reading out, amplifying and/or comparing the electrical signal of the active-pixel sensor. In other words, the active-pixel sensor according to the invention and/or the method according to the invention is applicable to a circuit following the active-pixel, such as a column amplifier or a first stage of a column ADC, to a comparator or to an amplifier/buffer.

The present invention also provides an active-pixel sensor including an electromagnetic radiation detector, comprising an analogue memory element having a first electrode and a second electrode, a transistor amplifier having an input and an output, wherein the input of the transistor amplifier is coupled to the electromagnetic radiation detector for generating an electrical signal output having a magnitude that is a function of the charge input generated by the electromagnetic radiation detector, and an output stage, wherein the first electrode is adapted for being coupled to a first reference voltage via a first variable resistance and/or the second electrode is adapted for being coupled to a second reference voltage via a second variable resistance, and the analogue memory element is coupled in series between the transistor amplifier and the output stage.

Generally, the active-pixel sensor can be provided in different forms. However, it is preferred that the active-pixel sensor is provided as described further above. Preferably, the analogue memory element is provided as a capacitor. It is further preferred that the first variable resistance and/or the second variable resistance are provided as MOSFETs.

According to another preferred embodiment of the invention, the active-pixel sensor further comprises a switch coupled to the transistor amplifier for impressing an electrical signal from the transistor amplifier into the first electrode or into the second electrode, wherein the transistor amplifier, the first variable resistance and/or the second variable resistance are each provided as at least two variable resistances coupled in series, and the at least two variable resistances are adapted for being turned on and off. It is further preferred that each and/or all of the at least two variable resistances are adapted for being alternately, concurrently or first concurrently and then alternately turned on and off. Turning on concurrently each of the at least two variable resistances allows for obtaining a good initial signal level for preventing image lag. This is then followed by turning on and off the at least two variable resistances alternately for reducing or silencing the noise in the signal further.

These and other aspects of the invention will be apparent from and elucidated with reference to the embodiments described hereinafter.

### BRIEF DESCRIPTION OF THE DRAWINGS

FIG. 1 schematically shows an active-pixel sensor according to a preferred embodiment of the invention,

FIG. 2 schematically shows two reset MOSFETs in series according to a preferred embodiment of the invention in a simplified layout view, illustrating further how a small parasitic capacitance (9) can be obtained

FIG. 3 schematically shows another active-pixel sensor according to another preferred embodiment of the invention,

FIG. 4 schematically shows a feedback circuit for an active-pixel sensor according to another preferred embodiment of the invention,

FIG. 5 schematically shows an example of a reset sequence for an active-pixel sensor according to a preferred embodiment of the invention,

FIG. 6a schematically shows an active-pixel sensor according to a preferred embodiment of the invention having an in-the-pixel memory element. FIG. 6b is such embodiment with more switches (variable resistors) made double.

FIG. 7 is a variant of FIG. 6 with a pinned photodiode (PPD) and a transfer gate (TG) instead of a regular photodiode (floating diffusion). “prog” is a programmable capacitor that can be added in parallel to program the full well charge.

FIG. 8 is a variant of FIG. 6 with a single floating diffusion (photo diode) and two amplifier and memory stages in parallel connected to that same floating diffusion

FIG. 8a: first embodiment of such variant, with two amplifier stages, two memory elements and two output stages

FIG. 8b: other embodiment of such variant, with one amplifier stage, two memory stages and one output stage

FIG. 8c: timing showing alternating or pipelined image acquisition (integration) and readout

FIG. 9 (a, b, c) shows three phases in the CDS operation of the pixel in FIG. 6a, indication the roles of C_{MEM} and C_{P}.

### DETAILED DESCRIPTION OF THE ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Similarly, it is to be noticed that the term “coupled”, also used in the claims, should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

In embodiments of the present invention, the term “substrate” or “semiconductor substrate” may include any underlying material or materials that may be used, or upon which a device, a circuit or an epitaxial layer may be formed. In other alternative embodiments, this “substrate” may include a semiconductor substrate such as e.g. doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or a Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. The substrate may be a bulk wafer (e.g. a homogeneously doped wafer), or an epi wafer, which is a bulk wafer with a separately grown epitaxial layer on top with different dopant type and or concentration. The substrate may be a composite substrate and may also be not based on silicon or not even be a semiconductor. On top of the substrate a semiconductor layer (Si or other like Amorphous Si or selenium . . . ) can be deposited. Hence the substrate can be a bulk wafer, an epitaxial wafer, an SOI wafer, or a wafer with a top layer of semiconductor on top of a different material (like glass). The very top layer of the substrate is a semiconductor.

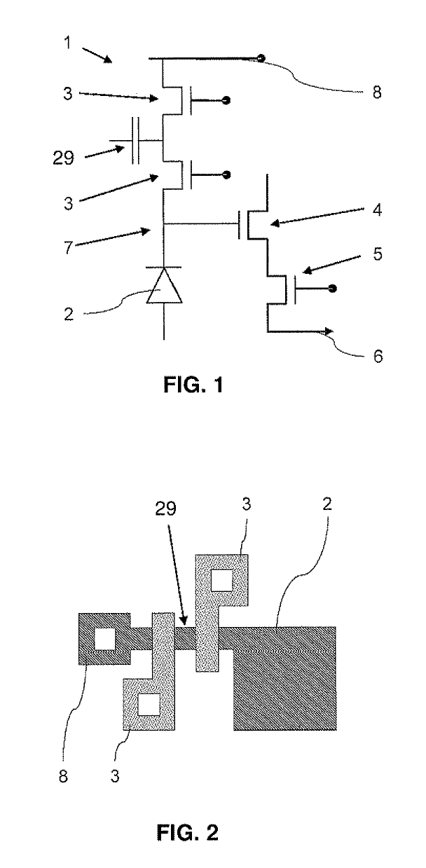

As can be seen from FIG. 1, according to a preferred embodiment of the invention, an active-pixel sensor 1 is provided, which comprises an electromagnetic radiation detector 2, which is provided as a photodiode, two variable resistances 3 coupled in series, which are provided as reset transistors, and more particular as MOSFETs, and a transistor amplifier 4, which is provided as a MOSFET as well.

The gate of the MOSFET transistor amplifier 4 is coupled to the electromagnetic radiation detector 2 for generating an electrical signal output having a magnitude that is a function of the charge input generated by the electromagnetic radiation detector 2. The electromagnetic radiation detector 2 is further coupled (at node 7) to two reset transistors 3 coupled in series with a reset capacitor 29 having on electrode connected at the node between the two reset transistors 3. The active-pixel sensor 1 according to the preferred embodiment of the invention comprises further a switch 5 coupled to the transistor amplifier 4 for impressing electrical signal from the transistor amplifier 4 into an output line 6. As it can be seen from FIG. 1, the switch 5 is provided as a MOSFET as well.

According to the preferred embodiment FIG. 1 of the invention, the floating diffusion is not reset in a single operation. Instead, it is iteratively reset to a reset voltage 8 (Vᵣₑₛₑₜ) by alternately turning on and off the reset transistors 3 coupled in series with each other in case of the so-called hard reset, or to a lower voltage, imposed by the reset transistors threshold voltage for the so-called soft reset.

After a number of iterations, whereby alternatingly the first and the second reset MOSFET 3 are on, and in a non overlapping fashion, the supply voltage (8) noise is then smoothed out during the multiple samples taken by the alternating operation of reset transistors 3. Also other noise mechanisms can be reduced or suppressed, such as noise due to instability of the VDD and GND supplies that drive the RESET signals itself, substrate noise and noise that enters the pixel or other sensitive circuits in various ways.

FIG. 2 schematically shows an example of how a low reset capacitance 29 (Cᵣ) can be designed in between two reset MOSFETs. 3

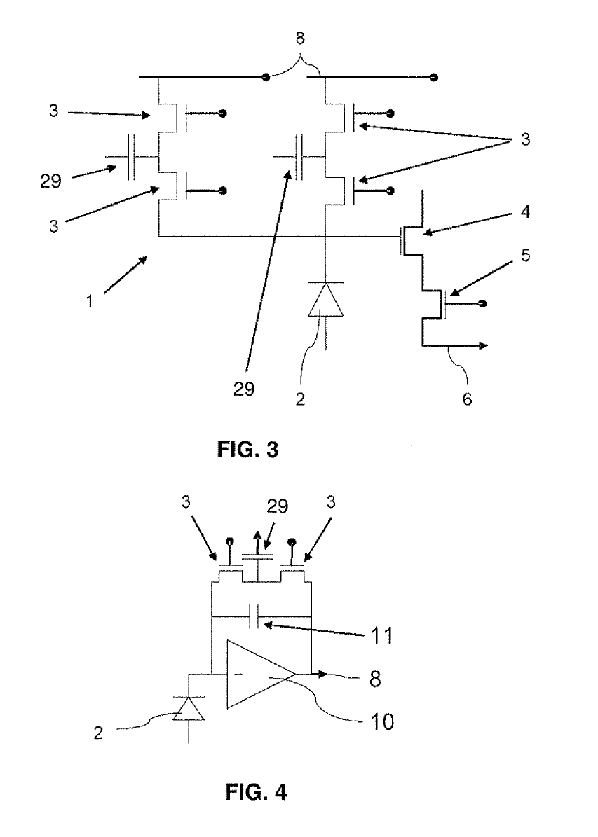

According to another preferred embodiment of the invention, as shown in FIG. 3, a plurality of serially coupled reset MOSFETs 3 can be provided in parallel. This is advantageous, since it can be first converged with a large reset capacitance 29 (Cᵣ), and then with a smaller step towards the final reset voltage.

Prior to alternatingly switching on and off the reset MOSFETs 3, all reset MOSFETs 3 can be turned on for obtaining a good initial signal level for preventing image lag. In other words, both reset MOSFETs 3 can be turned on in hard reset mode, followed by alternately turning on and off, which means the alternately turning on and off evolutes towards soft reset mode.

According to another preferred embodiment of the invention, as shown in FIG. 4, an output voltage of a feedback circuit 10, such as an amplifier, provides the reset voltage 8 (Vᵣₑₛₑₜ). In this manner, an amplifier capacitance 11 is provided. Alternatively, the reset voltage 8 (Vᵣₑₛₑₜ) can be provided as a DC voltage source. So-called column amplifiers are typically the first stages that transmit the electrical signal, i.e. from the output line 6, of the active-pixel sensor 1 via column lines. The column amplifiers can be provided as an analogue buffer driving a sample and hold stage or as a buffer in a multiplexing unit, which can be switched. Further, the column amplifier can be provided as a first or as any stage of a column ADC.

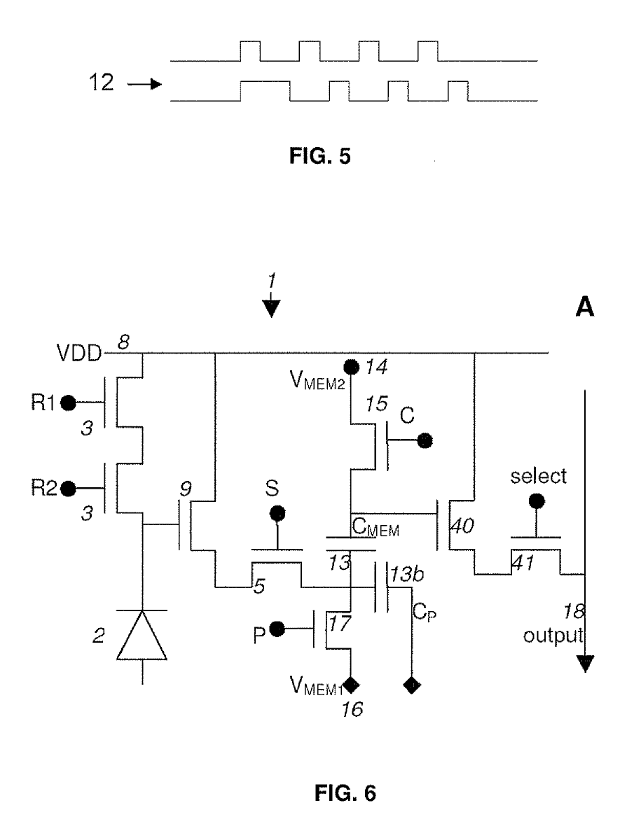

FIG. 5 schematically shows an example of a reset sequence 12 for an active-pixel sensor 1 according to another preferred embodiment of the invention. The reset sequence 12 can be applied to the two variable resistances 3 for resetting the active-pixel sensor.

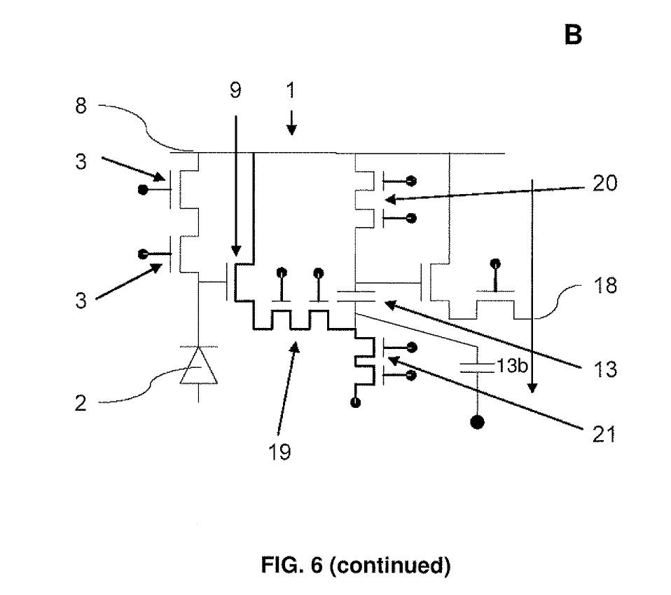

Further, in an embodiment of the present invention shown in FIG. 6a, a multiple stage active pixel sensor is provided. A first stage comprises one or more reset transistors (3), a photodiode (2) and a first amplifier (9). A second stage comprises or consists of a series storage capacitor (13), i.e. a storage capacitor located at a position between an output of the amplifier or output of the first stage and an output stage, a first variable resistor or switch (5) connecting the output of the first stage and a first electrode of the capacitor (13) and two (second and third) variable resistors (15 and 17) or switches each connecting respectively the first and a second electrode of the capacitor to respective first and second reference voltage signals (14 and 16). Finally the last or output stage comprises an amplifier (40), a fourth variable resistor (41) or switch, connecting the output of the pixel to a column readout (18). An advantage of this architecture is that it is as versatile as a so-called 4T pixel without requiring non-standard CMOS process.

FIG. 6b is also such an embodiment as shown in FIG. 6a but with more switches (variable resistors) 15, 17, e.g. made double. In order to reduce the kTC noise resulting from sampling the electrical signal on the analogue memory element 13, as depicted in FIG. 6b, the transistor amplifier 4, the first variable resistance 15 and the second variable resistance 17 are each provided as two variable resistances 19, 20, 21, i.e. MOSFETs, coupled in series. Prior to alternatingly switching on and off each of the two variable resistances 19, 20, 21 coupled in series, all MOSFETs can be turned on for obtaining a good initial signal level for preventing all image lag. In other words, all reset MOSFETs can be turned on in hard reset mode, followed by alternately turning on and off each of the two variable resistances 19, 20, 21 coupled in series, means the alternately turning on and off evolutes towards soft reset mode.

In FIGS. 6a and b a capacitor called “C_{P}” is used for some modes of operation to complement the storage capacitor “C_{MEM}”. Its use and importance will be described later. C_{P} has a value of the same order of magnitude as C_{MEM}. C_{P} can have a size relative to the memory capacitor C_{MEM} such that C_{P}>20% of C_{MEM}.

An array of such pixel structures is provided, e.g. in rows and columns. In a first mode of operation, the invented pixel structure is able to perform pipelined shutter operation. To do so, all photodiodes (2) of the array are reset simultaneously using the first variable resistor(s) 3 or switch(es) 3. In the FIGS. 6a and 6b two such switches 3 in series are shown, which may act also as a single switch or may be replaced by a single switch.

Then, after an exposure time, the second and third variable resistors 17 and 15 are set to low impedance, whereby the first voltage signal is a reference voltage (16) which could e.g. be at ground potential, and the second voltage signal being a reference voltage (14) at a higher or high voltage. Then simultaneously, the second variable resistors 17 of all pixels are set to high impedance, and the first variable resistor 5 is set to low impedance. This samples the output voltage of first stage onto the storage capacitor of the second stage. Then simultaneously, the first variable resistor 5 is set to high impedance, latching the pixel data. The third variable resistor (15) is set to high impedance, and second variable resistor (17) is set back to low impedance. The pixel data is then available for voltage readout using classically the last stage of the pixel. In addition to this operation, it is clear that the photodiode (2) can be reset again once the first variable resistor (5) is set to high impedance. The readout is independent of the integration and can be performed during the following frame integration time. Such mode of operation is called pipelined snapshot of pipelined synchronous shutter.

In a second mode of operation, the previously described reset and readout scheme can be applied on a row by row basis and not simultaneously on all pixels of the array. The pixel architecture does not limit the user to snapshot operation. Therefore, classic “rolling shutter” operation is possible.

In a third mode of operation, the pixel structure is capable of increasing the output voltage range of the pixel structure. In a first mode of operation, the column (18) voltage of the output stage is at best equal to the photodiode voltage minus two times the transistor threshold voltage due to the structure of first and last (output) stage amplifiers. Therefore, it is impossible to readout diode values lower than two time the transistor threshold value. The pixel architecture overcomes this limitation using the following operation. All photodiodes (2) of the array are reset simultaneously using the first variable resistor 3.

Then, after an exposure time, second and third variable resistors (17) and (15) are set to low impedance, the first voltage signal being a reference voltage (16) at ground potential, and the second voltage signal being a reference voltage (14) at a high or higher voltage. Then simultaneously, the second variable resistors (17) of all pixels are set to high impedance, and the first variable resistor (5) is set to low impedance. This samples the output voltage of first stage onto the storage capacitor of second stage. Then simultaneously, first variable resistor (5) is set to high impedance, latching the pixel data. The third variable resistor (15) is set to high impedance. The first voltage signal which is a reference voltage (16) is then brought to higher voltage than ground potential, 1.5V for instance, and the second variable resistor (17) is set back to low impedance. Doing so results in a voltage translation of the sampled voltage towards high voltage. The translation being the difference between second voltage signal which has a high value and ground. This compensates for the loss of one threshold voltage in the first stage of the pixel. As a result, the output voltage range of the pixel is increased. The pixel data is then available for voltage readout using classically the last stage of the pixel. In addition to this snapshot operation, it is clear that the photodiode (2) can be reset again once the first variable resistor (5) is set to high impedance. This mode of operation is thus also compatible with pipelined snapshot.

In a fourth mode of operation, the previously described reset and readout scheme can be applied on a row by row basis and not simultaneously on all pixels of the array. The invented pixel architecture does not limit the user to snapshot operation. Therefore, rolling shutter high output range is possible.

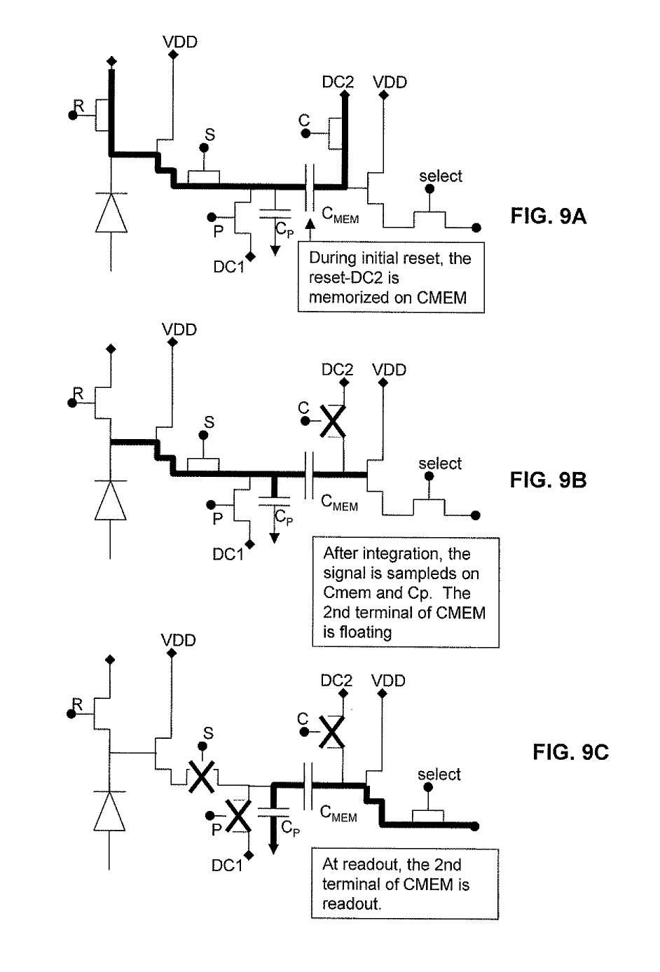

In a fifth mode of operation (which can be combined with several of the other modes listed above), the invented pixel is capable of performing correlated double sampling (CDS). On a row by row basis, the photodiode (2) is reset using the variable resistor or switch 3. The operation is schematically shown in FIG. 9.

The second and third variable resistors (17) and (15) are set to low impedance, The first voltage signal is a reference voltage (16) at ground potential, whereas the second voltage signal is a reference voltage (14) at a high or higher voltage. The first variable resistor (5) is set to low impedance. This samples the output voltage of first stage onto the storage capacitor of second stage. Then first variable resistor (5) is set to high impedance, latching the reset voltage of the photodiode. After integration time, the third variable resistor (15) is set to high impedance. The second variable resistor (17) is set back to low impedance. The first variable resistor (5) is set to low impedance and the last stage fourth variable resistance connecting the pixel second amplifier to the column select line (18) is set to low impedance. Across the storage capacitor (13), the actual reset voltage is subtracted from the signal voltage, performing a correlated double sampling without requiring additional CMOS process steps during manufacturing process.

In a sixth mode of operation, CDS operation is done in triggered synchronous shutter operation. It is similar to the fifth mode of operation and FIG. 9, yet, all switching of the variable resistors is done for all pixels in parallel, instead of row-by-row. Only at the moment of readout, the pixels data are read out row-by-row.

In order to have a good performance, particularly in this mode of operation, one needs a capacitor designated “C_{P}” to complement the memory element “C_{MEM}”. This capacitor C_{P} is necessary as, when the CDS is executed by opening the switches (e.g. variable resistances) in series with C_{MEM}, the capacitive load seen by the source followers driving C_{MEM}, becomes very low. As the source followers have a small load capacitance (“C_{load}”), their output voltage noise (proportional to \sqrt{k·T/C_{load}}) becomes too high and jeopardizes the noise suppressing properties of the CDS. Also, capacitor C_{P} is necessary to stabilize the voltage on the output source follower during subsequent readout, as in FIG. 9c. C_{P} must have a value of the same order of magnitude as C_{MEM} to have a sufficient stabilizing effect. C_{P} can have a size relative to the memory capacitor C_{MEM} such that C_{P}>20% of C_{MEM}.

Pixels capable of performing CDS are available as well in the literature. However, none of them is as versatile as the herein presented invention.

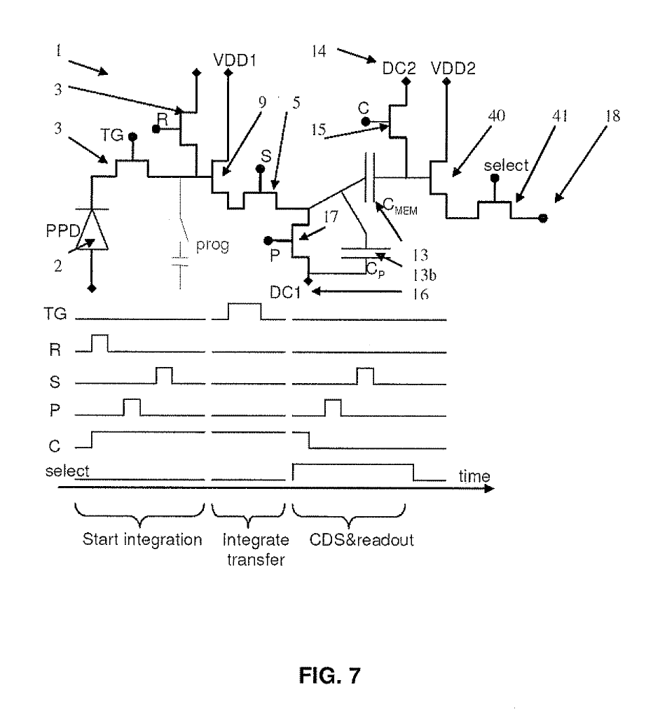

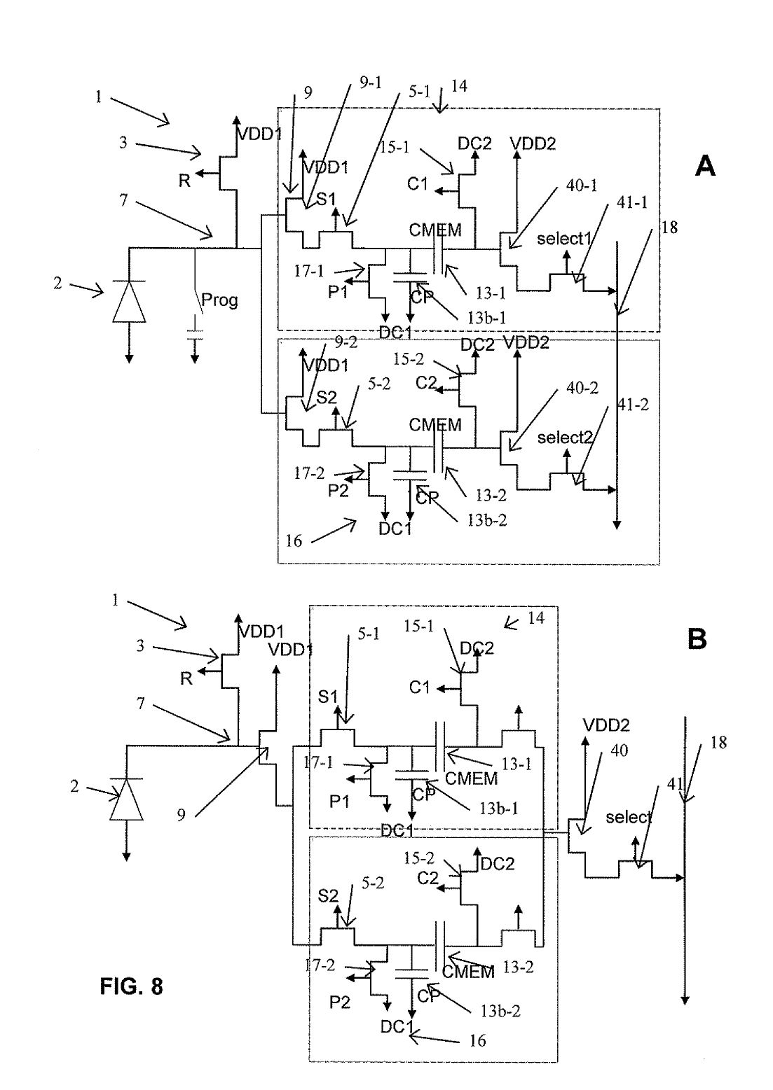

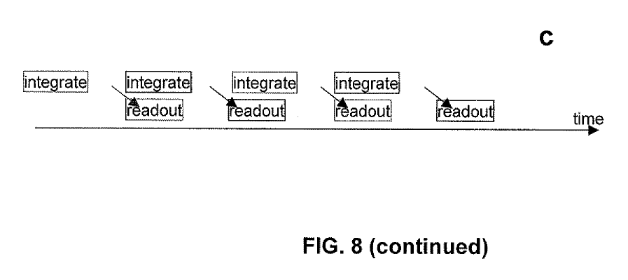

Further elaborations of the pixel structure in FIG. 6a are shown in FIGS. 7 and 8. These pixels can be understood to be derivatives of the pixel structure of FIG. 6a, and thus can execute all the modes of operation described above with reference to FIG. 6a, and additionally have the following features.

A pinned photodiode and optionally a transfer gate instead of the normal photodiode (or floating diffusion), as in FIG. 7. If such a transfer gate is present, one can essentially mimic the CDS capabilities of a pinned photodiode pixel as known from literature. CDS operation is done using the difference action across the C_{MEM} capacitor, and the result is being readout.

Optionally, two or more amplifier and memory stages may be used in parallel, serving a single photodiode node (or floating diffusion), as in FIG. 8. Such a pixel is capable to perform all operation modes listed above, and specifically for the non-pipelined (triggered) synchronous operation with CDS, to do it alternatingly on each of the two (or more) parallel stages, so that effectively a true pipelined synchronous operation with CDS is obtained, where the next frame is acquired while the previous frame is being readout.

The additional circuit components of the parallel circuits can be provided in a variety of ways. The reference numbers in FIGS. 8a and b relate to the same items as in FIG. 6. For first and second circuits a −1 or −2 is added. In FIG. 8A the following is duplicated:

Amplifier 9-1 and 9-2, switch transistor 5-1 and 5-2, switches 15-1, 15-2, 17-1, 17-2, capacitors 13-1 and 13-2, 13b-1 and 13b-2, and the output circuits 40-1, 41-1 and 40-2, 41-2.

In FIG. 8B the amplifier 9 is common as is the output circuit 40, 41. Intermediate components are duplicated—switch transistor 5-1 and 5-2, switches 15-1, 15-2, 17-1, 17-2, capacitors 13-1 and 13-2, 13b-1 and 13b-2.

This pixel (e.g. as shown in FIG. 8) can realize true CDS possible even in pipelined synchronous shutter operation. For that reason it needs, for example:

Two amplifier and memory stages (FIG. 8a) that operate in an alternating fashion:
one stage memorizes the reset level of the frame that is actually being integrated (acquired), and wait for the integration to complete so as to memorize the result on its C_{MEM}
the other stage is being readout.
During the next frame the roles are interchanged etcetera.

Note also that it is an obvious variant to combine the features of FIG. 7 and FIG. 8. i.e. a pixels with a pinned diode and an optional transfer gate, with two (or even more) parallel amplifier and memory stages.

An important aspect of the present inventions is the capacitor C_{P} at the entrance of the memory capacitor C_{MEM}. This same feature is used in the circuits of FIG. 6a or b, FIG. 7 and FIG. 8 resulting also there in a better CDS noise performance.

Comparison table below shows an overview of the modes of operation of the pixels shown and their performance levels.

| | FIG. 6a or b | FIG. 7 | FIG. 8 |
|---|---|---|---|
| photodiode | “normal diode” | Pinned diode | “normal diode” |
| | (Or any other | | Or any other |
| | photoreceptor) | | photoreceptor |
| Circuit size | 7T or more | 8T or more | 13T or more |
| Noise in pipelined | Has kTC noise | Cancels (reduces) | Cancels (reduces) |
| synchronous | | kTC by CDS on | kTC by CDS on |
| shutter | | the pinned diode/ | two sets of C_{MEM} |
| | | floating diffusion | |
| Noise in rolling | Cancels | Cancels (reduces) | Cancels (reduces) |
| shutter | (reduces) | kTC by CDS | kTC by CDS |
| | kTC by CDS | | |
| Noise in triggered | Cancels | Cancels (reduces) | Cancels (reduces) |
| shutter (i.e. | (reduces) | kTC by CDS | kTC by CDS |
| integration is | kTC by CDS | | |
| separate | | | |
| from read) | | | |

With reference to the series-connected memory capacitance C_{MEM} and stabilization capacitance C_{P}, in FIG. 9 it is shown schematically how C_{MEM} and C_{P} play a role in CDS operation. At the beginning of the integration cycle, the reset value is memorized on C_{MEM} (FIG. 9a). After that the charge is integrated on the floating diffusion. After the integration time, the signal is put on the 1^{st} terminal of C_{MEM} (FIG. 9b). Note that if C_{P} were not present, the voltage put on said 1^{st} terminal would not be stable as it would be on a high impedance node, with little or no capacitative decoupling, as the other terminal of C_{MEM} is floating. For that reason one needs a capacitor such as C_{P}, and C_{P} must have a significant value compared to C_{MEM}. One can typically use C_{MEM}=C_{P}, but also higher or lower C_{P} will work. The value on the 2nd terminal of C_{MEM} is essentially equal to the reset level minus the signal level, apart form some offset. The scheme performs thus essentially correlated double sampling.

Now, at the moment of readout, the value on the 2nd terminal of C_{MEM} is brought to the outside (FIG. 9c). The scheme performs correlated double sampling, which removes kTC noise of the photodiode or floating diffusion. It is worthwhile noting that the scheme does not cancel FPN (“fixed pattern noise”) on the output stage. It also does not cancel kTC noise of the C_{MEM} and C_{P} themselves. But with proper choice of the sizes of C_{MEM} and C_{P} significantly larger than the capacitance of the floating diffusion, this can be made negligible.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. An active pixel including an electromagnetic radiation detector, comprising a transistor amplifier generating an electrical signal having a magnitude that is a function of the charge input generated by the electromagnetic radiation detector, a series connected memory capacitor located between the transistor amplifier and an output stage and a parallel connected load capacitor connected between the transistor amplifier and the series connected memory capacitor and a DC node, wherein the parallel connected load capacitor has a size similar to the memory capacitor.

2. An active pixel according to claim 1, wherein the transistor amplifier is a source follower, connected via at least one switch to the series memory capacitor.

3. An active pixel according to claim 1, wherein the parallel connected load capacitor C_{P} has a size relative to the memory capacitor C_{MEM} such that C_{P}>20% of C_{MEM}.

4. An active pixel according to claim 1 wherein the electromagnetic radiation detector is a pinned photodiode connected via a transfer gate to the transistor amplifier.

5. An active pixel according to claim 1 wherein the electromagnetic radiation detector is connected via one or more parallel transistor amplifiers to at least two memory capacitors and via these two memory capacitors to at least 1 output stage.

6. An active pixel according to claim 1 further comprising
the memory capacitor having a first electrode and a second electrode,
the transistor amplifier having an input and an output, wherein the input of the transistor amplifier is coupled to the electromagnetic radiation detector, for generating an electrical signal output having a magnitude that is a function of the charge input generated by the electromagnetic radiation detector, and
an output stage
wherein
the first electrode is adapted for being coupled to a first reference voltage via a first variable resistance and/or the second electrode is adapted for being coupled to a second reference voltage via a second variable resistance, and
the analogue memory element is coupled in series between the transistor amplifier and the output stage.

7. An active pixel according to claim 6, comprising
a switch coupled to the transistor amplifier for impressing an electrical signal from the transistor amplifier into the first electrode or into the second electrode, wherein
the transistor amplifier, the first variable resistance and/or the second variable resistance are each provided as at least two variable resistances coupled in series, and
the at least two variable resistances are adapted for being turned on and off.

8. An active pixel comprising a transistor amplifier having an input and an output, wherein the input of the transistor amplifier is coupled to an electromagnetic radiation detector for generating an electrical signal output having a magnitude that is a function of the charge input generated by the electromagnetic radiation detector, and one or more variable resistances coupled in series, the active pixel comprising:
A first switch connecting the output of said amplifier to a first node of a capacitor,
Two switches connecting both nodes of the said capacitor to respectively two reference voltages,
the active pixel comprising an output stage comprising:
An amplifier having an input and an output, wherein the input of the transistor amplifier is coupled the second node of said capacitor,
A switch connecting the output of the amplifier to column.

9. The active pixel according to claim 8 wherein the reference voltage levels can be modified externally.

10. An image sensor comprising a plurality of active pixels according to claim 1.

11. Active pixel sensor including an electromagnetic radiation detector, comprising:
a transistor amplifier having an input and an output, wherein the input of the transistor amplifier is coupled to the electromagnetic radiation detector for generating an electrical signal output having a magnitude that is a function of the charge input generated by the electromagnetic radiation detector;
at least two variable resistances coupled in series, wherein
the at least two variable resistances are adapted for being turned on and off for resetting the charge input to the transistor amplifier to a predetermined signal level, and wherein
the first variable resistance is coupled to the electromagnetic radiation detector.

12. Active pixel sensor according to claim 11, wherein the at least two variable resistances are adapted for being alternately, or first concurrently and then alternately turned on and off.

13. Active pixel sensor according to claim 11, wherein the last variable resistance is coupled to a DC voltage source.

14. Active pixel sensor according to claim 11, wherein the last variable resistance is coupled to an output of feedback circuit which is adapted for sensing the charge input.

15. Active pixel sensor according to claim 11, wherein the electromagnetic radiation detector is provided as a monolithic or hybrid photodiode or as monolithic or hybrid photoresistor.

16. Active pixel sensor according to claim 11, wherein a plurality of at least two variable resistances coupled in series are provided in parallel.

17. Active pixel sensor according to claim 11, wherein the variable resistance includes a transistor having a first main electrode, a second main electrode, and a gate, and wherein the gate is adapted to receive a reset signal.

18. Method for resetting an active pixel sensor, comprising the step of alternately turning on and off at least two variable resistances coupled in series for resetting a node to a predetermined reset level.

19. Method according to claim 18, further comprising the step of concurrently turning on the at least two variable resistances prior to alternately turning on and off the at least two variable resistances.

20. Method according claim 18, further comprising the step of loading the at least two variable resistances in series with a DC voltage.

21. Method according to claim 18, further comprising the step of loading the at least two variable resistances in series with a voltage which is an output of a feedback circuit sensing the charge input.
